(19) United States
(12) Patent Application Publication
(10) Pub. No.: US 2010/0163102 A1
(43) Pub. Date: Jul. 1, 2010

(54) SOLAR CELL AND THE METHOD OF MANUFACTURING THEREOF

(75) Inventors: Wen-Hsien HO, Keelung City (TW); Chi-Sheng Jiang, Tu-Chen City (TW)

Correspondence Address: RABIN & Berdo, PC, 1101 14TH STREET, NW, SUITE 500, WASHINGTON, DC, 20005, US

(73) Assignee: TAIWAN TEXTILE RESEARCH INSTITUTE, Tu-Chen City (TW)

(21) Appl. No.: 12/346,796

(22) Filed: Dec. 30, 2008

(51) Int. Cl. H01L 31/0264; H01L 31/04; C23C 14/34; C23C 14/58

(52) U.S. Cl. 136/256; 204/192.1

(57) ABSTRACT

A solar cell comprises a substrate, a titanium oxide sputtering layer, at least one titanium oxide porous layer, a counter electrode and an electrolyte. The titanium oxide sputtering layer is sputtered on the substrate. The titanium oxide porous layer comprises a stack of titanium dioxide particles on the titanium oxide sputtering layer. The counter electrode is arranged on the titanium oxide porous layer. The electrolyte is filled between the counter electrode and the substrate.

### BACKGROUND

1. Field of Invention

The present invention relates to a solar cell. More particularly, the present invention relates to a composite solar cell and a method of manufacturing thereof.

2. Description of Related Art

Dye-sensitized solar cells (DSSC) are solar cells that convert solar energy absorbed into electricity via photochemical reactions by using a dye-photosensitizer. During manufacturing the photo-electrode of dye-sensitized solar cells, TiO₂ particles need to be coated on a substrate first and then sintered at high temperature to form a coating film on the substrate. However, such high temperature process is adverse to plastic substrates.

In addition, for various manners of manufacturing the photo-electrode, although wet coating can be performed at a room temperature, the adhesion between coated film and substrate was poor. The film produced by physical deposition has better adhesion, but the deposition efficiency is bad and it is hard to achieve the thickness desired.

Therefore, it needs to develop a method of manufacturing a solar cell which can be performed at room temperature. Meanwhile, the efficiency of the solar cell, the enough thickness of the photo-electrode, and poor adhesion of the coated film at a low temperature can be improved.

### SUMMARY

It is therefore an aspect of the present invention to provide a solar cell and a method of manufacturing thereof in order to be performed at a room temperature and to improve the thickness of the photo-electrode and the adhesion of the coated film at a low temperature.

According to the above, a solar cell is provided. It comprises a substrate, a titanium oxide sputtering layer, at least one titanium oxide porous layer, a counter electrode, and an electrolyte. The compact titanium oxide layer is sputtered on the substrate. The titanium oxide porous layer comprising a plurality of titanium dioxide particles stacked on the titanium oxide sputtering layer. The counter electrode is arranged on the titanium oxide porous layer. The electrolyte is filled between the counter electrode and the substrate.

According to one embodiment of the present invention, the thickness of the titanium oxide sputtering layer is less than 100 nm. The thickness of the titanium oxide porous layer is less than 20 μm. The specific surface area of the titanium dioxide particles is 2.0-165 cm²/g.

It is another aspect of the present invention to provide a method of manufacturing a solar cell, comprising providing a substrate; sputtered titanium oxide on the substrate to form a titanium oxide sputtering layer; coated the titanium oxide on the titanium oxide sputtering layer; compressing the dispersive titanium oxide particle solution to form a titanium oxide porous layer; absorbing a dye; and assemble an counter electrode.

According to one embodiment of the present invention, the step of sputtered titanium oxide on the substrate is performed at a room temperature by using a titanium oxide target. The step of sputtering is performed at a chamber pressure of 1-7 mTorr. The concentration of titanium oxide particle solution is 1%-20%.

Accordingly, compared with the conventional method, the method provided in the embodiment of the present application can be performed at a room temperature to manufacture a solar cell mentioned above. Moreover, by forming a titanium oxide sputtering layer and at least one titanium oxide porous layer on the photo-electrode, it not only achieves a desirable thickness, but also enhances photoelectric conversion efficiency.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a flow chart of manufacturing a solar cell according one embodiment of the present invention; and

FIG. 2 is a cross section view of the structure of the solar cell manufactured by the method shown in FIG. 1.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

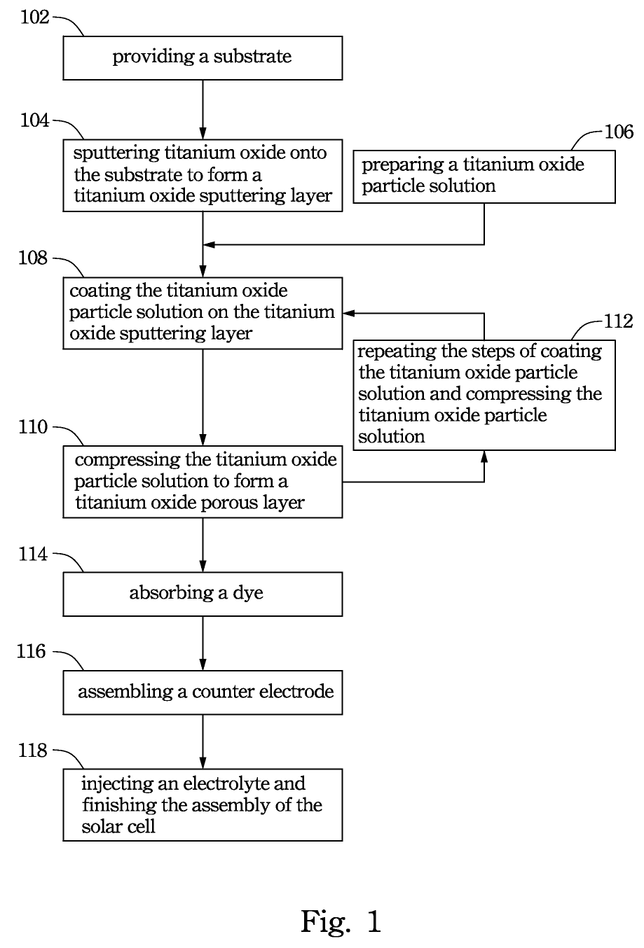

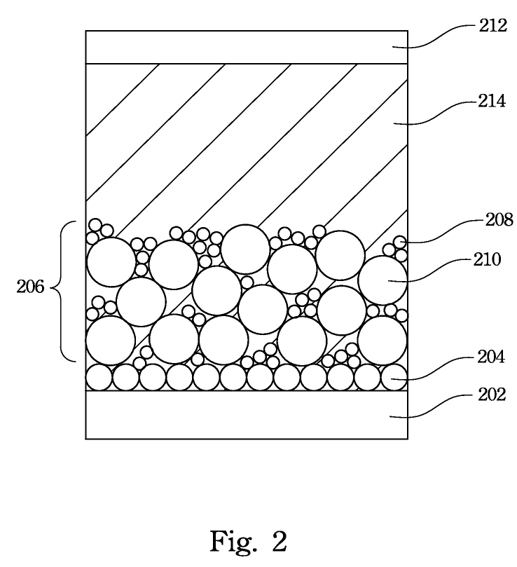

FIG. 1 illustrates a flow chart of a method of manufacturing a solar cell according to one embodiment of the present invention. FIG. 2 illustrates a cross section view of the structure of the solar cell manufactured by using the method shown in FIG. 1. Now, refer to FIGS. 1 and 2 for further details. First, providing a substrate 202 (step 102). The material of the substrate 202 can be transparent conductive oxide, such as indium tin oxide/poly(ethylene naphthalene-2,6-dicarboxylate) (ITO/PEN), ITO/PET, FTO/glass, ITO/glass, or metal. Next, at a room temperature, in a chamber pressure of 1-7 mTorr, a titanium oxide target is used to sputter titanium oxide onto the substrate 202 to form a titanium oxide sputtering layer 204 (step 104). The material of the titanium oxide sputtering layer 204 is titanium dioxide and the thickness thereof is less than 100 nm.

Meanwhile, titanium dioxide particles are dissolved in an absolute alcohol to prepare a titanium oxide particle solution (step 106). The specific surface area of the titanium dioxide particles used is 2.0-165 cm²/g and the crystalline phase is rutile or anatase. The concentration of titanium oxide particle solution prepared is 1%-20%. After that, the titanium oxide particle solution is coated on the titanium oxide sputtering layer 204, and the coating height is around 10 μm (step 108). Next, the titanium oxide particle solution is compressed to form a titanium oxide porous layer 206 (step 110). At this step, the compressing force is 50 kg/cm²-150 kg/cm² and applied for 30-60 seconds. The titanium oxide porous layer 206 formed comprises many titanium dioxide particles and these titanium dioxide particles are stacked on the titanium oxide sputtering layer 204 previously formed.

Moreover, to obtain a photoelectrode with a desirable thickness, the steps of coating a titanium oxide particle solution and compressing the titanium oxide particle solution can be repeated sequentially (step 112) until the titanium oxide porous layer has a thickness less than 20 μm. Then, a dye is absorbed (step 114) so that the dye 208 is dispersed on the surface of the titanium dioxide particles 210 in the titanium oxide porous layer 206. The dye used can be N719 (cis-bis(isothiocyanato)bis(2,2′-bipyridyl-4,4′-dicarboxylato)-ruthenium(II), bis-tetrabutylammonium), N3 (cis-bis(isothiocyanato)bis(2,2′-bipyridyl-4,4′-dicarboxylato), Z-907 (cis-bis(isothiocyanato)(2,2′-bipyridyl-4,4′-dicarboxylato)(2,2′-bipyridyl-4,4′-di-no nyl) ruthenium(II)), N-749 (tris(isothiocyanato)-ruthenium(II)-2,2′:6′,2″-terpyridine-4,4′,4″-tricarboxylic acid, tris-tertrabutylammonium salt), Ruthenium 470 (tris(2,2′bipyridyl-4,4′dicarboxylato) ruthenium (II) dichloride), and Ruthenium 505 (2,2′bipyridyl-4,4′dicarboxylato) ruthenium (II)). After absorbing the dye, a counter electrode 212 is assembled and arranged on the titanium oxide porous layer 206 (step 116). The material of the counter electrode 212 can be Pt, C, conductive polymer or transparent conductive oxide (TCO). Finally, an electrolyte 214 is injected between the counter electrode 212 and the substrate 210 and a solar cell is obtained (step 118). The electrolyte 214 used comprises LiI, I₂, 4-tert-Butylpyridine and acetonitrile.

In the following content, to test the effect of each manufacturing parameter on the efficiency of the solar cell during the manufacturing process, solar cells are fabricated by changing various manufacturing parameters and efficiency thereof is tested by photo-electrochemical measurements.

### Example 1

### The Effect of Chamber Pressure

In the embodiment of the present invention, several solar cell samples are prepared while the chamber pressure is changed during the preparation process for each sample to verify the effect of the chamber pressure on the efficiency of the solar cell obtained. The parameters for preparing each sample are listed in the table 1.

In addition, in the embodiment, titanium oxide sputtering layer is sputtered by using a titanium oxide target and the power density provided for all samples is 4.9 W/cm², and the ratio of gas flow rate in the chamber is Ar:O₂=15:2 sccm and the working distance is 7 cm.

As to the titanium oxide porous layer, it is prepared by dispersing titanium dioxide particles (i.e. P25 powder) in 99.5% absolute alcohol to form a titanium oxide particle solution, and then coating the titanium oxide particle solution onto the titanium oxide sputtering layer with blade. After finishing the first coating, the titanium oxide particle solution is compressed with a compressing force of 50 kg/cm² for 30 seconds at a room temperature to form a first titanium oxide porous layer. In order to obtain a photo-electrode with a desirable thickness, a second titanium oxide porous layer is formed. The second titanium oxide porous layer is formed by applying a compressing force of 150 kg/cm² for 60 seconds at 140° C. Finally, the dye, N719, is absorbed for at least 7 hours and platinum is used as a counter electrode and assembled. The electrolyte used comprises 0.5 M LiI, 0.05 M I₂, 0.5 M 4-tert-Butylpyridine, which is prepared in a 99% acetonitrile solution.

TABLE 1
parameters of TiO₂

| | | | | | Titanium oxide porous layer | | | |
|---|---|---|---|---|---|---|---|---|
| | | | | | | | | Compressing |
| | | | | | | | | force applied |
| | Titanium oxide sputtering layer | | | | | | Height of | to each |
| | Chamber | | Sputtering | Bias | TiO₂ specific | TiO₂ | Coating each | layer (kg/cm²)/ |
| | pressure | Thickness | duration | applied | surface area | Concentration | time | compressing |
| Sample | (mTorr) | (nm) | (min) | (V) | (m²/g) | (%) | (μm) | duration (s) |
| a | 1.3 | 60 | 90 | 50 | 50.94 | 20 | 10 | 50/30; |
| b | 2.6 | 50 | | | | | | 150/60 |
| c | 6.8 | 50 | | | | | | |

After obtaining the solar cell samples mentioned above, samples a-c are tested by photo-electrochemical measurements with light irradiation 1000 W/m² (AM 1.5). Since the atmosphere layer will absorb or scatter the sunlight before it reaches the surface of the earth, the path length of transmitting through the atmosphere layer is called AM (air mass). AM 0 corresponds to the solar spectrum in outer space. For a path through the atmosphere that is perpendicular to the earth's surface (the shortest path from outer space to the earth surface), AM is 1. AM 1.5 indicates the zenith angle for the sun is 48.19°. In general, the standard condition for testing a solar cell is AM 1.5.

The photo-electrochemical measurements include open circuit voltage (Voc), short circuit current (Isc), fill factor (FF) and photoelectric conversion efficiency (η). The testing results for each sample are listed in the table 2.

In the table 2, open circuit voltage and short circuit current are two important characteristics of solar cells. Open circuit voltage is the voltage difference across the cell, and it occurs when there is no current passing through the cell. It is also the maximum possible voltage can be provided by the cell.

Short circuited current represents to the light current produced by photon excitation while the solar cell corresponds to the short circuit condition (i.e. V=0). This can be maximum current value that produced by the solar cell. Therefore, the larger the values of open circuit voltage and short-circuited current are, the better photoelectric conversion efficiency of the solar cell.

Fill factor is essentially a measure of quality of the solar cell. It is calculated by comparing the practical maximum power (Pmax=(I×V)ₘₐₓ) to the theoretical power (i.e. the product of the open circuit voltage and short circuit current) of the solar cell. The formula is for calculating the fill factor as follows:

FF=Pₘₐₓ/(I_{sc}×V_{oc})=(I×V)ₘₐₓ/(I_{sc}×V_{oc})

Photoelectric conversion efficiency (η) is the ratio of the maximum power output (Pₘₐₓ) of unit illuminated area of the solar cell compared to the solar energy density input (P_{light}). The higher the photoelectric conversion efficiency, the better the solar cell performance. The formula for calculating the photoelectric conversion efficiency is as follows:

$$η ( \% ) = \frac{{( I \times V )}_{max}}{{P}_{light}} \times 100 \%$$

TABLE 2
the effect of different chamber pressure on the performance of the
solar cell manufactured

| | The | | | | |
|---|---|---|---|---|---|
| | parameter | | | | |
| | compared: | | short | | |
| | chamber | | circuit | | photoelectric |
| Sam- | pressure | open circuit | current | | conversion |
| ple | (mTorr) | voltage (V) | (mA/cm²) | fill factor | efficiency (%) |
| a | 1.3 | 0.74 | 0.01 | 0.23 | 0.01 |
| b | 2.6 | 0.73 | 4.63 | 0.19 | 0.63 |
| c | 6.8 | 0.77 | 13.10 | 0.32 | 3.22 |

According to the results shown in FIG. 2, it is found that for the solar cells manufactured in the chamber pressure of about 1-7 mTorr on basis of the method of the embodiment above, as the chamber pressure is increased, the short circuit current and the photoelectric conversion efficiency can be raised to 13.1 mA/cm² and 3.22%, respectively.

### Example 2

### The Effect of the Size of Titanium Dioxide Particles

In order to verify how the size of the titanium dioxide particles affects the performance of the solar cell, in this embodiment, titanium dioxide particles with different specific surface areas are used directly to prepare several solar cell samples without sputtering the titanium oxide sputtering layer on the substrate. The steps of manufacturing process have already mentioned in example 1, so it will not be described again herein. Only the manufacturing parameters are listed in the table 3.

TABLE 3
parameters of TiO₂

| | | Titanium oxide porous layer | | | | |
|---|---|---|---|---|---|---|
| | | | | | Height | |
| | | | | | of | Compressing force |
| | Titanium oxide | | | | Coating | applied to each |
| | sputtering | TiO₂ specific | | | each | layer(kg/cm²)/ |
| | layer | surface area | crystalline | TiO₂ | time | compressing |
| Sample | N/A | (m²/g) | phase | Concentration(%) | (μm) | duration(s) |
| d | N/A | 2.60 | Rutile | 10 | 10 | 50/30; |
| e | | 7.39 | Rutile | | | 150/60; |
| f | | 163.00 | Rutile | | | 150/60 |
| g | | 50.94 | Anatase | | | |
| h | | 130.42 | Anatase | | | |

Similarly, after finishing preparing each solar cell, it is tested by photo-electrochemical measurements. The testing results for samples d-h are listed in the table 4.

TABLE 4
the effect of different chamber pressure on the performance of the solar cell
manufactured

| | The parameter | | | | | |
|---|---|---|---|---|---|---|
| | compared: | | | | | |
| | TiO₂ specific | | | short circuit | | photoelectric |
| | surface area | crystalline | open circuit | current | | conversion |
| Sample | (m²/g) | phase | voltage (V) | (mA/cm²) | fill factor | efficiency (%) |
| d | 2.60 | Rutile | 0.71 | 1.22 | 0.42 | 0.36 |
| e | 7.39 | Rutile | 0.71 | 2.22 | 0.46 | 0.72 |
| f | 163.00 | Rutile | 0.69 | 2.70 | 0.54 | 1.00 |
| g | 50.94 | Anatase | 0.75 | 11.13 | 0.36 | 3.02 |
| h | 130.42 | Anatase | 0.76 | 4.77 | 0.35 | 1.26 |

According to the testing results of samples d-f, when the crystalline phase is rutile, the photoelectric conversion efficiency is improved from 0.36% to 1.00% as the specific surface area of the titanium dioxide particles increases from 2.6 m²/g to 163 m²/g. However, if the crystalline phase is anatase (sample g-h), the larger the specific surface area of the titanium dioxide particles is, the less the short circuit current and the photoelectric conversion efficiency. In view of the above, for the solar cell manufactured by the method of the embodiment of the present invention, the value of photoelectric conversion efficiency is changed on the basis of the difference of the crystalline phase and the size of the specific surface area of the titanium dioxide.

### Example 3

### The Effect of the Bias

In order to verify the effect of applying a bias on the efficiency of the solar cell during sputtering the titanium oxide sputtering layer, in this embodiment, solar cell samples are manufactured under the condition of applying a bias of 50 V or without applying a bias. The manufacturing parameters are listed in the table 5.

TABLE 5
parameters of TiO₂

| | | | | | Titanium oxide porous layer | | | |
|---|---|---|---|---|---|---|---|---|
| | | | | | | | | Compressing |
| | | | | | TiO₂ | | | force applied to |
| | Titanium oxide sputtering layer | | | | specific | | Height of | each layer |
| | Chamber | | Sputtering | Bias | surface | TiO₂ | Coating | (kg/cm²)/ |
| | pressure | Thickness | duration | applied | area | Concentration | each time | compressing |
| Sample | (mTorr) | (nm) | (min) | (V) | (m²/g) | (%) | (μm) | duration(s) |
| i | 2.6 | 35 | 90 | N/A | 50.94 | 20 | 10 μm | 50/30; |
| j | | 50 | | 50 V | | | | 150/60 |

The photo-electrochemical measurement results of solar cell samples i-j are listed in table 6.

TABLE 6
the effect of applying a bias on the performance of the solar cell
manufactured

| | The | | short | | |
|---|---|---|---|---|---|
| | parameter | | circuit | | photoelectric |
| | compared: | open circuit | current | fill | conversion |
| Sample | Bias applied | voltage (V) | (mA/cm²) | factor | efficiency (%) |
| i | 0 | 0.72 | 5.67 | 0.15 | 0.60 |
| j | 50 V | 0.73 | 4.63 | 0.19 | 0.63 |

According to table 6, it is found that for the solar cell manufactured by applying a bias of 0-50 V, the photoelectric conversion efficiency is around 0.6% and does not change a lot.

### Example 4

### The Effect of the Concentration of Titanium Oxide Particle Solution

Next, in order to verify the effect of concentration of titanium oxide particle solution on the efficiency of the solar cell during manufacturing the titanium oxide porous layer, in this embodiment, without sputtering the titanium oxide sputtering layer on the substrate, different concentrations of titanium oxide particle solution are coated on the substrate to form the titanium oxide porous layers and to prepare solar cell samples. The manufacturing parameters are listed in the table 7.

TABLE 7
parameters of TiO₂

| | | Titanium oxide porous layer | | | |
|---|---|---|---|---|---|
| | Titanium | TiO₂ | | | |
| | oxide | specific | | Height of | |
| | sputtering | surface | TiO₂ | Coating | Compressing force applied |
| | layer | area | Concentration | each time | to each layer (kg/cm²)/ |
| Sample | N/A | (m²/g) | (%) | (μm) | compressing duration(s) |
| k | N/A | 50.94 | 10 | 10 | 50/30; |
| l | | | 20 | | 150/60 |

The photo-electrochemical measurement results of solar cell samples k−1 are listed in table 8.

TABLE 8
the effect of the concentration of titanium oxide particle solution on the
performance of the solar cell manufactured

| | The parameter | | | | |
|---|---|---|---|---|---|
| | compared: | open | short | | photoelectric |
| | Concentration of | circuit | circuit | | conversion |
| | titanium oxide | voltage | current | fill | efficiency |
| Sample | particle solution (%) | (V) | (mA/cm²) | factor | (%) |
| k | 10 | 0.77 | 9.62 | 0.35 | 2.58 |
| l | 20 | 0.73 | 11.20 | 0.30 | 2.46 |

According to table 8, for the solar cells manufactured with the concentration of titanium oxide particle solution of 10-20%, the photoelectric conversion efficiency thereof can be maintained at around 2.5%.

### Example 5

### The Effect of the Thickness of the Titanium Oxide Sputtering Layer

In order to verify the effect of the thickness of the titanium oxide sputtering layer on the efficiency of the solar cell during manufacturing titanium oxide sputtering layer, in this embodiment, the titanium oxide sputtering layers with different thicknesses are sputtered on the substrate respectively to manufacture solar cell samples. The manufacturing parameters are listed in the table 9.

TABLE 9
parameters of TiO₂

| | | | | | Titanium oxide porous layer | | | |
|---|---|---|---|---|---|---|---|---|
| | | | | | | | Height | |
| | | | | | TiO₂ | | of | Compressing force |
| | Titanium oxide sputtering layer | | | | specific | | Coating | applied to each layer |
| | Chamber | | Sputtering | Bias | surface | TiO₂ | each | (kg/cm²)/ |
| | pressure | Thickness | duration | applied | area | Concentration | time | compressing |
| Sample | (mTorr) | (nm) | (min) | (V) | (m²/g) | (%) | (μm) | duration(s) |
| m | 6.8 | 20 | 15 | 80 | 50.94 | 20 | 10 | 50/30; |
| n | | 30 | 30 | | | | | 150/60 |
| o | | 65 | 60 | | | | | |
| p | | 70 | 90 | | | | | |
| q | | 90 | 120 | | | | | |

The photo-electrochemical measurement results of each solar cell sample are listed in table 10.

TABLE 10
the effect of the thickness of titanium oxide sputtering layer
on the performance of the solar cell manufactured

| | The parameter compared: | | short circuit |
|---|---|---|---|
| | Thickness of Titanium oxide | open circuit | current |
| Sample | sputtering layer (μm) | voltage (V) | (mA/cm²) |
| m | 20 | 0.66 | 2.18 |
| n | 30 | 0.62 | 2.22 |
| o | 65 | 0.63 | 1.38 |

According to table 10, it is found that as the thickness of the titanium oxide sputtering layers increases, the short circuit current decreases.

### Example 6

### The Effect of Sputtering Method and the Compressed-Coating Method on the Adhesion

Finally, in order to verify the effect of adhesion, samples r and s are prepared by sputtering a 50 nm titanium oxide sputtering layer and compressing a titanium oxide porous layer, respectively. Then, the adhesion test, ASTM D 3359-95m, is performed. The manufacturing parameters and the testing results are listed in the table 11.

TABLE 11
parameters of TiO₂ and the result of adhesion test
Titanium oxide sputtering layer

| | | | | | | | | |
|---|---|---|---|---|---|---|---|---|
| | | | | | | Height | Compressing | |
| | | | | TiO₂ | | of | force applied to | |
| | | | | specific | | Coating | each layer | |
| | Chamber | Sputtering | Bias | surface | TiO₂ | each | (kg/cm²)/ | |
| | pressure | duration | applied | area(m²/ | Concentration | time | compressing | Adhesion |
| Sample | (mTorr) | (min) | (V) | g) | (%) | (μm) | duration(s) | level |

| | | | | | |
|---|---|---|---|---|---|
| r | 6.8 | 90 | 50 | N/A | 4 B |

| | | | | | | |
|---|---|---|---|---|---|---|
| s | N/A | 50.94 | 1 | 10 | 50/30 | 3 B |

According to table 11, it is found that even though having the same thickness, the titanium oxide sputtering layer formed by sputtering has better adhesion compared with the titanium oxide porous layer manufactured by compressing. Therefore, the adhesion can be improved by adding the titanium oxide sputtering layer on the substrate.

Finally, comparing the testing results of sample l and sample c, it is found that the photoelectric conversion efficiency of the solar cell sample l which is without the titanium oxide sputtering layer is only 2.46%. However, for the composite solar cell sample c which has the both titanium oxide sputtering layer and the titanium oxide porous layer, its photoelectric conversion efficiency can reach 3.22% that is increased around 30%. In view of the above, by having the both titanium oxide sputtering layer and the titanium oxide porous layer to manufacture a photo-electrode, it not only obtains a desirable thickness via sputtering and coating several layer, but also improves the adhesion of low-temperature coated films and the photoelectric conversion efficiency. Meanwhile, the efficiency of the solar cell can also be increased by changing different manufacturing parameters.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar cell, comprising:
a substrate;
a titanium oxide sputtering layer sputtered on the substrate;
at least one titanium oxide porous layer comprising a plurality of titanium dioxide particles stacked on the titanium oxide sputtering layer;
a counter electrode arranged on the titanium oxide porous layer; and
an electrolyte filled between the counter electrode and the substrate.

2. The solar cell of claim 1, wherein the thickness of the titanium oxide sputtering layer is less than 100 nm.

3. The solar cell of claim 1, wherein the titanium oxide sputtering layer is made of titanium dioxide.

4. The solar cell of claim 1, wherein the thickness of the titanium oxide porous layer is less than 20 μm.

5. The solar cell of claim 1, wherein the crystalline phase of the titanium dioxide particles are rutile or anatase.

6. The solar cell of claim 1, wherein the specific surface area of the titanium dioxide particles is 2.0-165 cm²/g.

7. The solar cell of claim 1, further comprising a dye which is dispersed on the surface of the titanium dioxide particles.

8. The solar cell of claim 7, wherein the dye is N719 (tris(2,2′bipyridyl-4,4′dicarboxylato) ruthenium (II) dichloride).

9. The solar cell of claim 1, wherein the material of the substrate is indium tin oxide/poly(ethylene naphthalene-2,6-dicarboxylate), transparent conductive oxide or metal.

10. The solar cell of claim 1, wherein the electrolyte comprises LiI, I₂, 4-tert-Butylpyridine and acetonitrile.

11. The solar cell of claim 1, wherein the material of the counter electrode is Pt, C, conductive polymer or transparent conductive oxide.

12. A method of manufacturing a solar cell, comprising:
providing a substrate;
sputtering titanium oxide on the substrate to form a titanium oxide sputtering layer;
coating a titanium oxide particle solution on the titanium oxide sputtering layer;
compressing the titanium oxide particle solution to form a titanium oxide porous layer;
absorbing a dye; and
assemble a counter electrode.

13. The method of claim 12, wherein the step of sputtering titanium oxide on the substrate is performed at a room temperature by using a titanium oxide target.

14. The method of claim 12, wherein the step of sputtering is performed at a chamber pressure of 1-7 mTorr.

15. The method of claim 12, wherein the thickness of the titanium oxide sputtering layer is less than 100 nm.

16. The method of claim 12, wherein the titanium oxide particle solution is prepared by dissolving a plurality of titanium dioxide particles in an absolute alcohol.

17. The method of claim 16, wherein the concentration of titanium oxide particle solution is 1%-20%.

18. The method of claim 16, wherein the specific surface area of the titanium dioxide particles is 2.0-165 cm²/g.

19. The method of claim 16, wherein the crystalline phase of the titanium dioxide particles are rutile or anatase.

20. The method of claim 12, wherein at the step of coating a titanium oxide particle solution, the coating height of the titanium oxide particle solution is 10 μm.

21. The method of claim 12, wherein at the step of compressing the titanium oxide particle solution, the compressing duration is 30-60 seconds.

22. The method of claim 12, wherein at the step of compressing the titanium oxide particle solution, the compressing force is 50 kg/cm²-150 kg/cm².

23. The method of claim 12, further comprising repeating the step of coating a titanium oxide particle solution and the step of compressing the titanium oxide particle solution sequentially before performing the step of absorbing a dye until the titanium oxide porous layer has a thickness less than 20 μm.

24. The method of claim 12, wherein the material of the substrate is indium tin oxide/poly(ethylene naphthalene-2,6-dicarboxylate), transparent conductive oxide or metal.

25. The method of claim 12, wherein the material of the counter electrode is Pt, C, conductive polymer or transparent conductive oxide.

26. The method of claim 12, wherein the dye is N719 (tris(2,2′bipyridyl-4,4′dicarboxylato) ruthenium (II) dichloride).

27. The method of claim 12, further comprising injecting an electrolyte between the counter electrode and the substrate.

28. The method of claim 27, wherein the electrolyte comprises LiI, I₂, 4-tert-Butylpyridine and acetonitrile.

29. The method of claim 12, wherein the step of sputtering titanium oxide on the substrate comprises applying a bias of 0-50 V to the substrate.
